(19) United States
(12) Patent Application Publication
(10) Pub. No.: US 2021/0103214 A1
(43) Pub. Date: Apr. 8, 2021

(54) RED COLOR FILTER PHOTORESIST

(71) Applicant: TCL China Star Optoelectronics Technology Co., Ltd., Shezhen, Guandong (CN)

(72) Inventors: Bao ZHA, Shenzhen, Guangdong (CN); Ji Li, Shenzhen, Guangdong (CN)

(21) Appl. No.: 16/615,738

(22) PCT Filed: Aug. 28, 2019
(86) PCT No.: PCT/CN2019/102941

§ 371 Date: Nov. 21, 2019

(30) Foreign Application Priority Data
Jul. 17, 2019 (CN) 201910644754.3

(51) Int. Cl. G03F 7/004; G03F 7/00; C09B 11/24

(52) U.S. Cl. CPC G03F 7/0045; C09B 11/24; G03F 7/0007

(57) ABSTRACT

The present invention relates a red color filter photoresist. The present invention adopts rhodamine and its derivatives with high dye uptake as a red dye, in combination with red and yellow pigment systems, to form a mixed dye-pigment red color filter photoresist that satisfies current requirements of wide color gamut and processing requirements of LCDs, which prevents that development of red color filter photoresist stagnates and leads to problems of products such as white points and dark state color points, and is advantageous to realize a liquid crystal display with wider color gamut.

### FIELD OF INVENTION

The present invention relates to a red color filter photoresist.

### BACKGROUND OF INVENTION

Color filter photoresists are an important part of liquid crystal displays. Currently, in order to develop a wide color gamut color filter photoresist, the main approach changes thickness of a layer of the color filter photoresist and relative proportions of pigment. Subject to processing factors of a color filter photoresist, it is necessary to control thickness of films within a certain range, and also have relative proportions of pigments in materials to be within a reasonable range; otherwise degree of difficulty during processing of color filter photoresist will be higher.

### SUMMARY OF INVENTION

Currently, blue and green color filter photoresist both have dye with high dye uptake to replace a pigment system, development of red color filter photoresist still stagnates so far, and a promising dye is still unfound, which will cause many problems of products such as white points and dark state color points; therefore, development of a red dye system to replace a red pigment system is in urgent need such that a liquid crystal display (LCD) with wider color gamut can be realized.

One purpose of the present invention is to provide a red color filter photoresist that can resolve the problem that the conventional red color filter photoresist is subject to factors of processing and materials and thus the development stagnates, to realize a liquid crystal display with wider color gamut.

In order to resolve the above-mentioned problem, an embodiment of the present invention provides a red color filter photoresist that, in mass percentage, includes a colorant, wherein the colorant includes red dye, and the red dye includes rhodamine and its derivatives.

Furthermore, wherein the red color filter photoresist, in mass percentage, comprising: resin, 5-10%; photopolymerization monomer, 4-7%; photoinitiator, 0.8-1.5%; additives, 2-2.5%; solvent, 45-60%; and the colorant, 16-35%.

Furthermore, wherein the colorant includes red pigment, wherein the red pigment accounts for 11-22% of the red color filter photoresist in mass percentage, and the red pigment includes a red pigment whose type is R244; and yellow pigment, wherein the yellow pigment accounts for 4-8% of the red color filter photoresist in mass percentage, and the yellow pigment includes a yellow pigment whose type is Y150; wherein the rhodamine and its derivatives account for 1-5% of the red color filter photoresist in mass percentage.

Furthermore, wherein the rhodamine and its derivatives is a rhodamine 640 derivative with structural formula as the following:

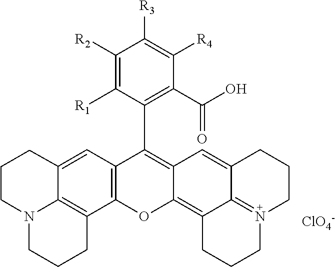

wherein R1-R4 of the structural formula includes one or more of a halogen substituent, an amino group, a carboxyl group, a hydroxy, a sulfuric group, an aldehyde, an ester group, an acyl group, a cyano group, a nitro, an amino group, a phenyl group, a phenol, a long chain molecule with an ester group, derivatives of a halogenated alkane, a conjugated structure and a non-conjugated structure bonded by an alkoxy group and an ester group, and a heterocyclic compound.

Furthermore, wherein the halogen substituent includes one or more of fluorine, chlorine, bromine, and iodine; the non-conjugated structure includes one or more of a straight chain alkane, a branch chain alkane, a straight chain alkane of an alkoxy, and a branch chain alkane of an alkoxy; the heterocyclic compound includes one or more of a five-membered heterocyclic compound, a six-membered heterocyclic compound, a benzo heterocyclic compound, and a condensed heterocyclic compound; wherein the five-membered heterocyclic compound includes at least one of furan, thiophene, pyrrole, thiazole, or imidazole; wherein the six-membered heterocyclic compound includes at least one of pyridine, pyrazine, pyrimidine, or diazine; wherein the condensed heterocyclic compound includes at least one of indole, quinoline, pteridine, or acridine.

Furthermore, wherein the resin includes an acrylic resin, and the acrylic resin includes at least one of poly(dimethylaminoethyl methacrylate), poly(butyl methacrylate), hydroxyethyl methacrylate, poly(cyclohexyl methacrylate), or poly(2-Ethylhexyl methacrylate).

Furthermore, wherein the photopolymerization monomer includes at least one of ethyl acrylate, butyl acrylate, 2-ethylhexyl acrylate, methyl methacrylate, styrene, lauryl methacrylate, or 2-ethylhexyl acrylate.

Furthermore, wherein the photoinitiator includes acetophenone derivatives, and the acetophenone derivatives include at least one of α,α-diethoxyacetophenone, 2-methyl-2-morpholino-1-(4-methylphenylthio)propan-1-one, or 2-hydroxy-2-methylpropiophenone.

Furthermore, wherein the additives include silane coupling agent.

Furthermore, wherein the solvent includes at least one of PGMEA, PGME, or MEA.

The present invention relates a red color filter photoresist. The present invention adopts rhodamine and its derivatives with high dye uptake as a red dye, in combination with red and yellow pigment systems, to form a mixed dye-pigment red color filter photoresist that satisfies current requirements of wide color gamut and processing requirements of LCDs, which prevents that development of red color filter photoresist stagnates and leads to problems of products such as white points and dark state color points, and is advantageous to realize a liquid crystal display with wider color gamut.

### DETAILED DESCRIPTION OF PREFERRED EMBODIMENTS

The embodiments of the present invention are described in detail hereinafter. Examples of the described embodiments are given in the accompanying drawings. It should be noted that the following embodiments are intended to illustrate and interpret the present invention, and shall not be construed as causing limitations to the present invention. Similarly, the following embodiments are part of the embodiments of the present invention and are not the whole embodiments, and all other embodiments obtained by those skilled in the art without making any inventive efforts are within the scope protected by the present invention.

In the description of the present invention, it should be understood that terms such as “upper,” “lower,” “front,” “rear,” “left,” “right,” “inside,” “outside,” as well as derivative thereof should be construed to refer to the orientation as shown in the drawings under discussion. These relative terms are for convenience of description and shall not be construed as causing limitations to the present invention.

In the accompanying drawings, the identical reference numerals constantly denote the same structural elements, the similar reference numerals constantly denote components with a similar structure or function. Furthermore, in order to facilitate understanding and description, dimensions and thickness of each component shown in the accompanying drawings are arbitrary, and the present invention does not limit dimensions and thickness of each component.

When components are described as “on” another component, the components can be directly placed on the another component; there can also be an intermediate component, that is, the components are placed on the intermediate component, and the intermediate component is placed on the another component. When a component is described as “mounted to” or “connected to” another component, they can be understood as directly “mounted” or “connected”, or one component is “mounted to” or “connected to” another component by an intermediate component.

### First Embodiment

The present embodiment provides a red color filter photoresist that, in mass percentage, includes a colorant, 16-35%; resin, 5-10%; photopolymerization monomer, 4-7%; photoinitiator, 0.8-1.5%; additives, 2-2.5%; and solvent, 45-60%.

Wherein, the colorant includes red dye, red pigment, yellow pigment. Wherein, the red pigment accounts for 11-22% of the red color filter photoresist in mass percentage, and the yellow pigment accounts for 4-8% of the red color filter photoresist in mass percentage. Wherein, the red dye includes rhodamine and its derivatives. Wherein, the rhodamine and its derivatives account for 1-5% of the red color filter photoresist in mass percentage.

Wherein, the absorption light band of the rhodamine 640 derivative is mainly concentrated in the yellow-green region, and therefore can be combined with red pigment and yellow pigment, and adjustment of the proportions can adjust color points of the red color filter.

Hence, wherein the red dye can be chosen from rhodamine 640 derivatives, whose chemical structural formula is as the following:

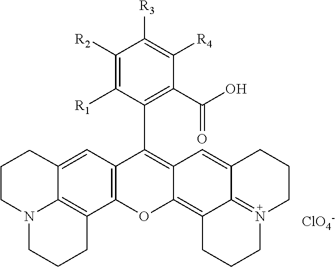

Wherein, R₁-R₄ of the chemical structural formula can be chosen from one or more of a halogen substituent, an amino group (—NH2), a carboxyl group (—COOH), a hydroxy (—OH), a sulfuric group (—SH), an aldehyde group (—COH), an ester group (—COO—), an acyl group (—COCl, —COBr), a cyano group (—CN), a nitro (—NO2), an amino group (—NH2, ═NH, and ≡N), a phenyl group, a phenol, a long chain molecule with an ester group, derivatives of a halogenated alkane, a conjugated structure and a non-conjugated structure bonded by an alkoxy group and an ester group, and a heterocyclic compound.

Wherein, the halogen substituent includes one or more of fluorine (—F), chlorine (—Cl), bromine (—Br), and iodine (—I).

Wherein, the non-conjugated structure includes one or more of a straight chain alkane, a branch chain alkane, a straight chain alkane of an alkoxy, and a branch chain alkane of an alkoxy.

Wherein, the heterocyclic compound includes one or more of a five-membered heterocyclic compound, a six-membered heterocyclic compound, a benzo heterocyclic compound, and a condensed heterocyclic compound.

In particular, wherein the five-membered heterocyclic compound includes at least one of furan, thiophene, pyrrole, thiazole, or imidazole.

In particular, wherein the six-membered heterocyclic compound includes at least one of pyridine, pyrazine, pyrimidine, or diazine.

In particular, wherein the condensed heterocyclic compound includes at least one of indole, quinoline, pteridine, or acridine.

Wherein, the red pigment can be chosen as a red pigment whose type is R244, and wherein the yellow pigment can be chosen as a yellow pigment whose type is Y150; therefore, the red dye rhodamine 640 derivative can be combined with the red pigment and the yellow pigment, and adjustment of the proportions can adjust color points of the red color filter.

In particular, wherein the resin includes an acrylic resin, and the acrylic resin includes at least one of poly(dimethylaminoethyl methacrylate), poly(butyl methacrylate), hydroxyethyl methacrylate, poly(cyclohexyl methacrylate), or poly(2-Ethylhexyl methacrylate).

In particular, wherein the photopolymerization monomer includes at least one of ethyl acrylate, butyl acrylate, 2-ethylhexyl acrylate, methyl methacrylate, styrene, lauryl methacrylate, or 2-ethylhexyl acrylate.

In particular, wherein the photoinitiator includes acetophenone derivatives, and the acetophenone derivatives include at least one of α,α-diethoxyacetophenone, 2-methyl-2-morpholino-1-(4-methylphenylthio)propan-1-one, or 2-hydroxy-2-methylpropiophenone.

In particular, wherein the additives include silane coupling agent.

In particular, wherein the solvent includes at least one of PGMEA, PGME, or MEA.

The red color filter photoresist adopting the above-mentioned materials can satisfy current requirements of wide color gamut and processing requirements of LCDs, which prevents that development of red color filter photoresist stagnates and leads to problems of products such as white points and dark state color points, and is advantageous to realize a liquid crystal display with wider color gamut.

Furthermore, the red color filter photoresist according to the present invention can also be used to manufacture red color filter. In particular, putting the above-mentioned red color filter photoresist that is uniformly mixed through coating, exposure and crosslink, and baking to obtain a red color filter, whose red color point can reach (0.678, 0.320) in CIE 1931 coordinate diagram, and in combination with blue and green color filter photoresist color filters with wide gamut, is advantageous to realize a liquid crystal display with wide color gamut.

The foregoing describes the red color filter photoresist according to the present invention in detail. It should be understood that illustrative embodiments described above are descriptive, intended to facilitate understanding of the approach and main idea of the present invention, and not intended to limit the present invention. Description of features or aspects in each illustrative embodiment should generally be considered to apply to similar features or aspects of other illustrative embodiments. Although illustrative embodiments describe the present invention, they can suggest to those skilled in the art making variations and modifications. The present invention intends to include the variations and modifications within the scope of the appended claims, and many changes and modifications to the described embodiments can be carried out without departing from the scope and the spirit of the present invention that is intended to be limited only by the appended claims.

What is claimed is:

1. A red color filter photoresist, comprising:
a colorant, wherein the colorant comprises red dye, and the red dye comprises rhodamine and its derivatives.

2. The red color filter photoresist as claimed in claim 1, in mass percentage, comprising:
resin, 5-10%;
photopolymerization monomer, 4-7%;
photoinitiator, 0.8-1.5%;
additives, 2-2.5%;
solvent, 45-60%; and
the colorant, 16-35%.

3. The red color filter photoresist as claimed in claim 1, wherein the colorant comprises:
red pigment, wherein the red pigment accounts for 11-22% of the red color filter photoresist by percent mass, and the red pigment comprises a red pigment whose type is R244; and
yellow pigment, wherein the yellow pigment accounts for 4-8% of the red color filter photoresist by percent mass, and the yellow pigment comprises a yellow pigment whose type is Y150;
wherein the rhodamine and its derivatives account for 1-5% of the red color filter photoresist by percent mass.

4. The red color filter photoresist as claimed in claim 1, wherein the rhodamine and its derivatives is a rhodamine 640 derivative with structural formula as the following: 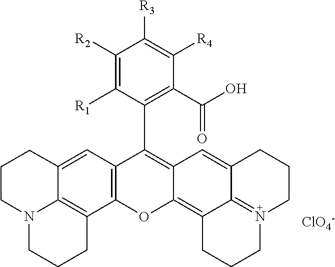
wherein R₁-R₄ of the structural formula comprises one or more of a halogen substituent, an amino group, a carboxyl group, a hydroxy, a sulfuric group, an aldehyde, an ester group, an acyl group, a cyano group, a nitro, an amino group, a phenyl group, a phenol, a long chain molecule with an ester group, derivatives of a halogenated alkane, a conjugated structure and a non-conjugated structure bonded by an alkoxy group and an ester group, and a heterocyclic compound.

5. The red color filter photoresist as claimed in claim 4, wherein the halogen substituent comprises one or more of fluorine, chlorine, bromine, and iodine;
the non-conjugated structure comprises one or more of a straight chain alkane, a branch chain alkane, a straight chain alkane of an alkoxy, and a branch chain alkane of an alkoxy;
the heterocyclic compound comprises one or more of a five-membered heterocyclic compound, a six-membered heterocyclic compound, a benzo heterocyclic compound, and a condensed heterocyclic compound;
wherein the five-membered heterocyclic compound comprises at least one of furan, thiophene, pyrrole, thiazole, or imidazole;
wherein the six-membered heterocyclic compound comprises at least one of pyridine, pyrazine, pyrimidine, or diazine;
wherein the condensed heterocyclic compound comprises at least one of indole, quinoline, pteridine, or acridine.

6. The red color filter photoresist as claimed in claim 2, wherein the resin comprises an acrylic resin, and the acrylic resin comprises at least one of poly(dimethylaminoethyl methacrylate), poly(butyl methacrylate), hydroxyethyl methacrylate, poly(cyclohexyl methacrylate), or poly(2-Ethylhexyl methacrylate).

7. The red color filter photoresist as claimed in claim 2, wherein the photopolymerization monomer comprises at least one of ethyl acrylate, butyl acrylate, 2-ethylhexyl acrylate, methyl methacrylate, styrene, lauryl methacrylate, or 2-ethylhexyl acrylate.

8. The red color filter photoresist as claimed in claim 2, wherein the photoinitiator comprises acetophenone derivatives, and the acetophenone derivatives comprise at least one of α,α-diethoxyacetophenone, 2-methyl-2-morpholino-1-(4-methylphenylthio)propan-1-one, or 2-hydroxy-2-methylpropiophenone.

9. The red color filter photoresist as claimed in claim 2, wherein the additives comprise silane coupling agent.

10. The red color filter photoresist as claimed in claim 2, wherein the solvent comprises at least one of PGMEA, PGME, or MEA.
